(19) United States
(12) Patent Application Publication
(10) Pub. No.: US 2024/0178118 A1
(43) Pub. Date: May 30, 2024

(54) PACKAGE SUBSTRATE AND SEMICONDUCTOR DEVICE

(71) Applicant: ABLIC Inc., Nagano (JP)

(72) Inventors: Masayoshi SHIMIZU, Nagano (JP); Mitsuhiro SAKUMA, Nagano (JP)

(21) Appl. No.: 18/505,418

(22) Filed: Nov. 9, 2023

(30) Foreign Application Priority Data
Nov. 30, 2022 (JP) 2022-191643
Mar. 9, 2023 (JP) 2023-036089

(51) Int. Cl. H01L 23/498; H01L 23/31

(52) U.S. Cl. CPC H01L 23/49822; H01L 23/3121; H01L 23/49838; H01L 24/48; H01L 2224/48227

(57) ABSTRACT

A package substrate on which a semiconductor chip in which circuit elements having different operating voltages exist in a mixed manner is mounted on a front surface side thereof, and in which electrical paths extending from the front surface side to a back surface side are formed for each of the operating voltages. IN the package substrate, the wiring layers having the different operating voltages are arranged so as to be spaced apart by predetermined distances in accordance with the operating voltages, and the wiring layers having the same operating voltage are arranged so as to overlap with each other in a plan view at least in the build-up layer.

### CROSS-REFERENCE TO RELATED APPLICATION

This application claims the priority benefits of Japanese patent application nos. 2022-191643, filed on Nov. 30, 2022 and 2023-036089 filed on Mar. 9, 2023. The entirety of above-mentioned patent applications are hereby incorporated by reference herein and made a part of this specification.

### BACKGROUND OF THE INVENTION

### 1. Field of the Invention

The present invention relates to a package substrate and a semiconductor device.

### 2. Description of the Related Art

Semiconductor packages of various structures have been developed in order to downsize semiconductor devices.

For example, there is given a semiconductor package in which a semiconductor chip is mounted on a ball grid array (BGA) substrate having solder balls arrayed on a back surface thereof in a grid pattern. Various proposals have been made on the BGA package substrate.

Specifically, in order to improve connection reliability and electrical characteristics, there is proposed a structure in which, for a BGA surface having an area larger than that of a semiconductor chip mounting surface, a gold plating layer is directly formed on a copper layer without interposing a nickel plating layer between the copper layer and the gold plating layer (see Japanese Patent Application Laid-open No. 2004-327940).

### SUMMARY OF THE INVENTION

At least one aspect of the present invention has an object to provide a package substrate capable of increasing a potential difference between wirings without increasing a size thereof in a multilayer substrate, thereby being capable of increasing reliability.

According to at least one embodiment of the present invention, there is provided a package substrate on which a semiconductor chip in which circuit elements having different operating voltages exist in a mixed manner is mounted on a front surface side thereof, and in which electrical paths extending from the front surface side to a back surface side are formed for each of the different operating voltages, the package substrate including: a base material being a flat plate-shaped insulator; a build-up layer which is formed on at least one of a front surface or a back surface of the base material, and in which a wiring layer and an insulating layer covering the wiring layer are alternately laminated; and vias which are formed in the base material and the insulating layer, and are each configured to electrically connect the wiring layers to each other, wherein the wiring layers having the different operating voltages are arranged so as to be spaced apart by predetermined distances in accordance with the different operating voltages, respectively, and wherein the wiring layers having the same operating voltage are arranged so as to overlap with each other in a plan view at least in the build-up layer.

According to the at least one aspect of the present invention, it is possible to provide the package substrate capable of increasing the potential difference between the wirings without increasing the size thereof in the multilayer substrate, thereby being capable of increasing the reliability.

### BRIEF DESCRIPTION OF THE DRAWINGS

FIG. 1 is a schematic sectional view for illustrating a semiconductor device according to at least one embodiment of the present invention.

FIG. 2 is a schematic sectional view for illustrating a package substrate according to the at least one embodiment.

FIG. 3 is a schematic sectional view for illustrating the package substrate according to the at least one embodiment.

FIG. 4A is a schematic plan view for illustrating the package substrate according to the at least one embodiment.

FIG. 4B is a schematic plan view for illustrating the package substrate according to the at least one embodiment.

FIG. 5A is an explanatory view for illustrating one state during a method of manufacturing the semiconductor device according to the at least one embodiment.

FIG. 5B is an explanatory view for illustrating one state during the method of manufacturing the semiconductor device according to the at least one embodiment.

FIG. 5C is an explanatory view for illustrating one state during the method of manufacturing the semiconductor device according to the at least one embodiment.

### DESCRIPTION OF THE EMBODIMENTS

A semiconductor device according to at least one embodiment of the present invention is achieved based on the following findings.

In the ball grid array (BGA) package substrate as described in Japanese Patent Application Laid-open No. 2004-327940, when circuit elements having different operating voltages exist in a mixed manner, an increase in potential difference between wirings increases an electric field. Consequently, migration is liable to occur, with the result that reliability may be decreased. In order to avoid such a decrease in reliability, it is required to check the degree of occurrence of migration due to, for example, a temperature and humidity in a usage environment and an intensity of the electric field generated between the wirings, and then space apart wiring layers having different operating voltages by predetermined distances in accordance with the operating voltages. It is preferred that a wiring distance be large in a case of a large voltage difference between wirings. In a case of wiring layers overlapping with each other in the multilayer substrate, it is preferred that the wiring distance in an interlayer direction (substrate thickness direction), that is, a thickness of an insulating layer, be large.

However, there is an upper limit to the thickness of the insulating layer. In some cases, depending on the magnitude of the voltage difference between wirings, the distance by which the wirings are to be spaced apart may become larger than the upper limit thickness of the insulating layer. In such case, the wirings having different potential differences cannot be installed in an up-and-down direction of the wirings so as to be opposed to each other. Accordingly, securing the wiring distance in an in-plane direction causes an increase in size of the package substrate. Thus, a wiring gap is increased in each wiring layer to reduce a remaining copper rate, with the result that an in-plane distribution of the wirings is less likely to be uniform and a difference in remaining copper rates is more liable to be generated. Consequently, a defect such as voids or deviation in press-fitting of pre-preg is more liable to occur during heating and pressing processing in a manufacturing process.

As described above, in the multilayer substrate having a large potential difference between wirings, there is a fear in that reliability is deceased due to the occurrence of migration. To increase the size of the multilayer substrate so as to avoid such situation not only causes an increase in frequency of defects due to the remaining copper rate but also goes against the trend of downsizing of semiconductor devices.

In view of the above, in a package substrate according to the at least one embodiment of the present invention, wiring layers having the same operating voltage are arranged so as to overlap with each other in a plan view.

With this arrangement, according to the package substrate of the at least one embodiment, even in a multilayer substrate, a potential difference between wirings can be increased without increasing a size thereof, thereby being capable of increasing reliability.

In the following, at least one mode for carrying out the present invention is described in detail with reference to the drawings.

The same components are denoted by the same reference symbols in the drawings, and overlapping description thereof is omitted in some cases.

Moreover, an X-axis, a Y-axis, and a Z-axis shown in the drawings are orthogonal to one another. In some cases, an X-axis direction is referred to as “width direction,” a Y-axis direction is referred to as “depth direction,” and a Z-axis direction is referred to as “height direction” or “thickness direction.” In addition, in some cases, a surface on a +Z-direction side of each film is referred to as “front surface” or “upper surface,” and a surface on a −Z-direction side of each film is referred to as “back surface” or “lower surface.”

Moreover, the drawings are merely schematic, and, for example, a ratio among width, depth, and thickness is not necessarily drawn to scale. The numbers, positions, shapes, structures, dimensions, and the like of a plurality of films or layers or semiconductor elements obtained by combining those films or layers in their structures are not limited to those described in the following at least one embodiment, and can be set to numbers, positions, shapes, structures, dimensions, and the like that are preferred in carrying out the present invention.

### At least One Embodiment

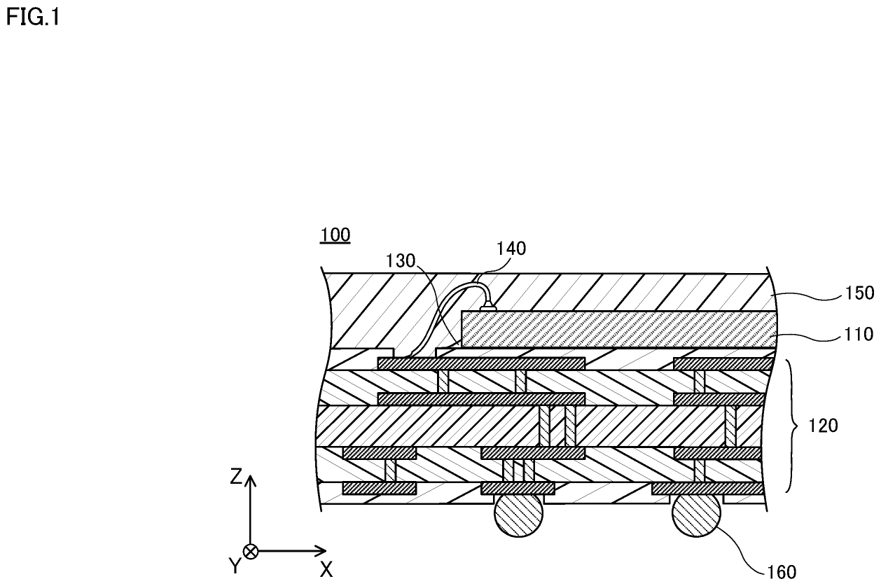

FIG. 1 is a schematic sectional view for illustrating a semiconductor device according to the at least one embodiment.

As illustrated in FIG. 1, a semiconductor device 100 is a ball grid array (BGA) package. The semiconductor device 100 includes a semiconductor chip 110, a package substrate 120, a conductive adhesive 130, a bonding wire 140, an encapsulating resin 150, and conductive bumps 160.

In the semiconductor chip 110, circuit elements having different operating voltages exist in a mixed manner. Two types of voltages, specifically, a low voltage of 3.3 V for operating an internal circuit of the semiconductor chip 110 and a high voltage of 100 V for operating an external device to be connected to the semiconductor device 100, exist in a mixed manner in the operating voltages of the semiconductor chip 110. Thus, voltages to be supplied to the package substrate 120 from an electrode pad that is provided on a front surface of the semiconductor chip 110 through the bonding wire 140 or voltages to be sent from the package substrate 120 to the electrode pad through the bonding wire 140 differ from each other, and the potential difference therebetween is large.

The circuit elements are, for example, transistors, diodes, capacitors, inductors, resistors, and other elements that can be formed on semiconductor chips.

The package substrate 120 has the semiconductor chip 110 mounted on a front surface thereof, and has the conductive bumps 160 formed on an electrode pad formed on a back surface thereof. In the package substrate 120, electrical paths extending from the electrode pad on the front surface to the electrode pad on the back surface having the plurality of conductive bumps 160 formed thereon are formed for each operating voltage of the semiconductor chip 110.

Details of the package substrate 120 are described later.

The conductive adhesive 130 is an adhesive containing a thermosetting epoxy-based resin as a main material and flaky silver. The conductive adhesive 130 is applied to the front surface of the package substrate 120, thereby bonding the semiconductor chip 110 to the front surface of the package substrate 120.

A material, composition ratio, viscosity, and application amount of the conductive adhesive 130 can be suitably selected as required.

Moreover, in the at least one embodiment, the conductive adhesive is employed. However, the adhesive is not limited thereto, and may be an insulating adhesive.

The bonding wire 140 electrically connects a bonding pad provided on the upper surface of the semiconductor chip 110 and an electrode pad on the front surface of the package substrate 120.

A material of the bonding wire 140 is not particularly limited and can be suitably selected. Examples of the material are Au, Cu, Al, Ag, or an alloy thereof.

The encapsulating resin 150 protects the semiconductor chip 110, the package substrate 120, the conductive adhesive 130, and the bonding wire 140, and forms an outer shape of the semiconductor device 100.

The encapsulating resin 150 is not particularly limited and can be suitably selected. An example of the encapsulating resin 150 is a thermosetting epoxy-based resin.

The conductive bumps 160 are solder balls, and are arrayed on the back surface of the package substrate 120. The conductive bumps 160 fuse due to heat of reflow soldering at the time of being mounted to a mounting substrate so that the semiconductor device 100 is mounted on the mounting substrate.

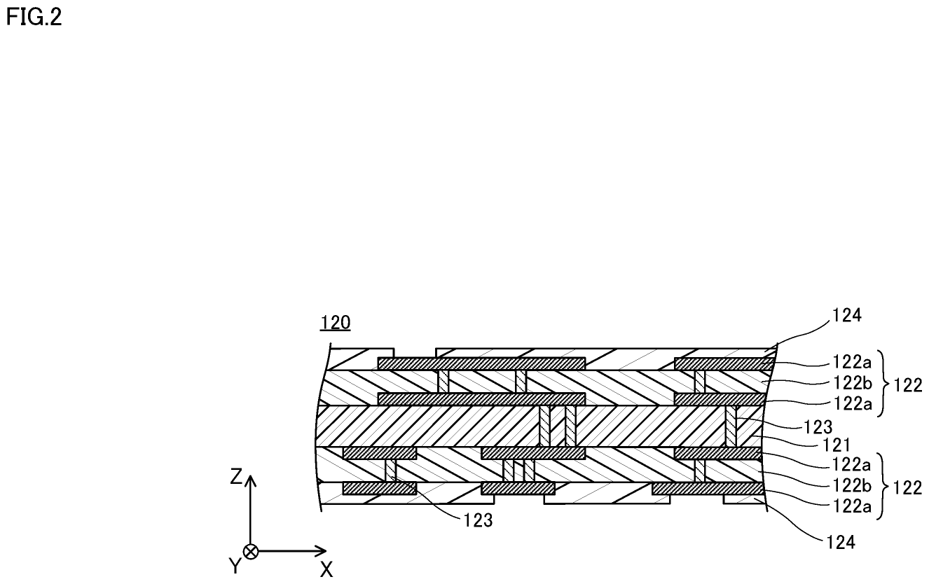

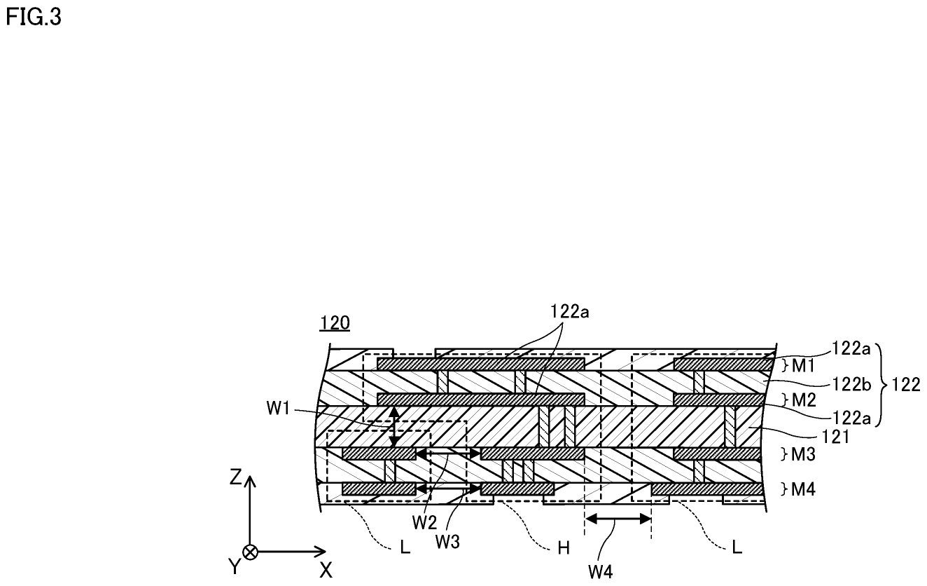

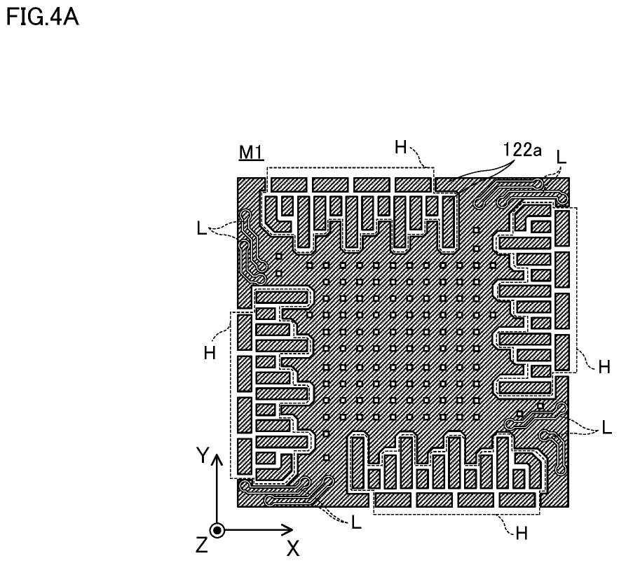

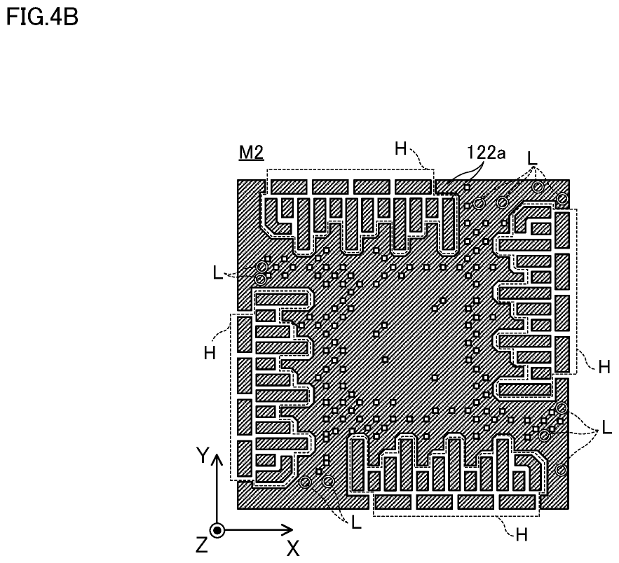

Next, the package substrate 120 is described in detail with reference to FIG. 2, FIG. 3, FIG. 4A, and FIG. 4B.

FIG. 2 is a schematic sectional view for illustrating the package substrate according to the at least one embodiment.

As illustrated in FIG. 1, the package substrate 120 has the semiconductor chip 110 mounted on the front surface side thereof, and the conductive bumps 160 formed on the back surface side thereof.

The package substrate 120 is a multilayer substrate, and includes a base material 121, build-up layers 122, a plurality of vias 123, and resist layers 124.

The base material 121 is a flat plate-shaped insulator, and has a thickness of about 100 μm.

A material of the base material 121 is formed of a bismaleimide-triazine (BT) resin.

While the BT resin is adopted in the at least one embodiment, polyimide, polyester, Flame Retardant Type 4 (FR-4), polytetrafluoroethylene (PTFE), composite epoxy material (CEM)-1, CEM-2, CEM-3, a metal such as aluminum, or the like may also be adopted.

The build-up layer 122 is formed on both of a front surface and a back surface of the base material 121. In the build-up layer 122, a wiring layer 122a and an insulating layer 122b covering the wiring layer 122a are alternately laminated. It is only required that the build-up layer 122 be formed on at least one of the front surface or the back surface of the base material 121. However, from a viewpoint of suppressing warpage of the package substrate 120, it is preferred that the number of layers on the front surface and the number of layers on the back surface be the same.

The wiring layer 122a is a copper foil in which a circuit pattern is formed by etching, and has a thickness of about 30 μm. Moreover, the wiring layers 122a are electrically connected to one another through the plurality of vias 123, to thereby form electrical paths for the low voltage having the operating voltage of 3.3 V and electrical paths for the high voltage having the operating voltage of 100 V.

The insulating layer 122b is formed of pre-preg being a composite material formed by impregnating sheet-shaped fibers with a resin.

A method of forming the insulating layer 122b is given as follows. The copper foil of the wiring layer 122a and the pre-preg in the form of resin-sheet in a semi-cured state are laminated on the front surface of the base material 121, and heating and pressing processing is performed thereon. In this case, the pre-preg in a cured state serves as the insulating layer 122b. Accordingly, a thickness of the insulating layer 122b is about 60 μm at a position at which the wiring layer 122a exists, and is about 90 μm at a position at which the wiring layer 122a does not exist. Moreover, in the heating and pressing processing, a lower remaining copper rate of the copper foil of the wiring layer 122a may cause a decrease in thickness of the insulating layer 122b in some cases. With this regard, in the at least one embodiment, the remaining copper rate can be increased. Thus, it is possible to avoid the decrease in thickness of the insulating layer 122b.

The plurality of vias 123 are formed in the base material 121 and the insulating layers 122b to form electrical paths extending from the front surface side to the back surface side of the package substrate 120 for each operating voltage.

The resist layers 124 protect both surfaces of the package substrate 120, and are made of solder resist ink.

A method of forming the resist layer 124 is given as follows. After the solder resist ink is applied to a front surface of the wiring layer 122a corresponding to an outermost layer of the build-up layer 122, light is applied so as to semi-cure the solder resist ink. Then, heating processing is performed so as to finally cure the solder resist ink, thereby obtaining the resist layer 124. Accordingly, a thickness of the resist layer 124 is about 30 μm at the position at which the wiring layer 122a exists, and is about 60 μm at the position at which the wiring layer 122a does not exist.

FIG. 3 is a schematic sectional view for illustrating the package substrate according to the at least one embodiment. In FIG. 3, a high voltage region H represents a region of the electrical paths to which the high voltage having the operating voltage of 100 V is applied, and low voltage regions L represent regions of the electrical paths to which the low voltage of 3.3 V is applied.

As illustrated in FIG. 3, in the high voltage region H, wirings to which the same high voltage of 100 V is applied are arranged so as to overlap with each other in an outer layer of an M1 layer and an inner layer of an M2 layer. Similarly to the M1 layer and the M2 layer, wirings to which the same high voltage of 100 V is applied are arranged so as to overlap with each other in an inner layer of an M3 layer and an outer layer of an M4 layer. Also in the low voltage region L, similarly to the high voltage region H, wirings to which the same low voltage of 3.3 V is applied are arranged so as to overlap with each other in an outer layer and an inner layer.

As described above, the package substrate 120 according to the at least one embodiment has a structure in which the wirings are arranged so as to overlap with each other in the outer layer and the inner layer.

Moreover, in at least one of the front surface or the back surface of the base material 121, a predetermined distance is secured as a clearance between the wiring layers 122a having different operating voltages. The predetermined distance in the at least one embodiment is set such that a predetermined distance S1 in the inner layer (M2 layer and M3 layer) is 100 μm or more and a predetermined distance S2 with the outer layer (M1 layer and M4 layer) is 130 μm or more. The predetermined distances S1 and S2 are set to be different for the following reason. A surface resistance of the outer layer is more liable to be smaller than a surface resistance of the inner layer even though the outer layer is coated with the resist layer 124. Thus, the predetermined distance S2 with the outer layer is required to be larger than the predetermined distance S1 in the inner layer.

Those predetermined distances can be suitably selected in accordance with, for example, a magnitude of the operating voltage.

A gap W1 between the inner layers having the base material 121 interposed therebetween is thus equal to a thickness of the base material 121 (100 μm), thereby satisfying the following equation: S1≤W1. A gap W2 within the same inner layer is 140 μm, thereby satisfying the following equation S1≤W2. Moreover, a gap W3 within the same outer layer is 140 μm, thereby satisfying the following equation: S2≤W3. A gap W4 between the inner layer and the outer layer is 140 μm, thereby satisfying the following equation: S2≤W4.

In FIG. 3, the gap W4 is set as a gap in a plan view, but the gap W4 may be set as a gap in consideration of a three-dimensional structure (gap in the Z-axis direction).

As described above, in the package substrate 120 according to the at least one embodiment, the wiring layers having different operating voltages are arranged so as to be spaced apart by the predetermined distances in accordance with the operating voltages, respectively.

Accordingly, in the package substrate 120 according to the at least one embodiment, even when the high voltage regions H and the low voltage regions L exist in a mixed manner, the high voltage regions H and the low voltage regions L are arranged so as to be spaced apart by the predetermined distances in accordance with the operating voltages, respectively. With this arrangement, even in the multilayer substrate, the package substrate 120 can increase the potential difference between the wirings without increasing the size thereof, thereby being capable of increasing the reliability.

Moreover, the thickness of the insulating layer 122b of the build-up layer 122 on the upper surface side of the base material 121 is about 60 μm at the position at which the wiring layer 122a exists. Thus, for example, when the inner layer of the wiring layer 122a is set as the high voltage region H, the predetermined distance S1 cannot be secured. Accordingly, the wiring layer 122a serving as the low voltage region L cannot be arranged in the outer layer above the high voltage region H in the inner layer. As a result, the remaining copper rate becomes low.

In view of this, in the at least one embodiment, the wiring layer 122a serving as the high voltage region H is arranged in the M1 layer so as to increase the remaining copper rate. Moreover, in a case of setting the M2 layer as the low voltage region L, the wiring layer 122a serving as the low voltage region L is arranged in the M1 layer above the low voltage region L in the M2 layer so as to increase the remaining copper rate. Application of this arrangement not only to the build-up layer 122 on the upper surface side of the base material 121 but also to the build-up layer 122 on the lower surface side of the base material 121 can increase the remaining copper rate of the wiring layers 122a as a whole. Accordingly, variation in thickness of the insulating layers 122b during the heating and pressing processing at the time of manufacturing the package substrate 120 can be suppressed. In addition, occurrence of defect such as voids or deviation in press-fitting of pre-preg can be suppressed. Moreover, a difference in remaining copper rates of the wiring layers 122a can be reduced, thereby being capable of suppressing warpage of the package substrate 120.

Moreover, in the high voltage region H, two wiring layers 122a formed in different layers are electrically connected to each other through two or more vias 123. With this connection, the wiring layers 122a in the high voltage region H have a uniform potential distribution within a plane, thereby being capable of forming the electrical paths which can allow a large current to flow therethrough.

FIG. 4A and FIG. 4B are each a schematic plan view for illustrating the package substrate according to the at least one embodiment. FIG. 4A is a schematic plan view of the M1 layer being the outer layer of the wiring layer 122a illustrated in FIG. 3. FIG. 4B is a schematic plan view of the M2 layer being the inner layer of the wiring layer 122a illustrated in FIG. 3.

When the wiring layers 122a in the M1 layer and the M2 layer are compared with each other, as illustrated in FIG. 4A and FIG. 4B, the high voltage regions H and the low voltage regions L are arranged such that the same regions overlap with each other.

In a portion in which the same regions overlap with each other, from a viewpoint of securing a clearance of the wirings in the M1 layer larger than a clearance of the wirings in the M2 layer, it is preferred that a wiring width on the M1 layer side be smaller than a wiring width of the M2 layer.

Moreover, in a region other than the high voltage regions H and the low voltage regions L, so-called “solid pattern” is formed in order to increase the remaining copper rate. It is preferred that the clearance with the solid pattern be a clearance in accordance with the voltages to be handled in the high voltage region H and the low voltage region L.

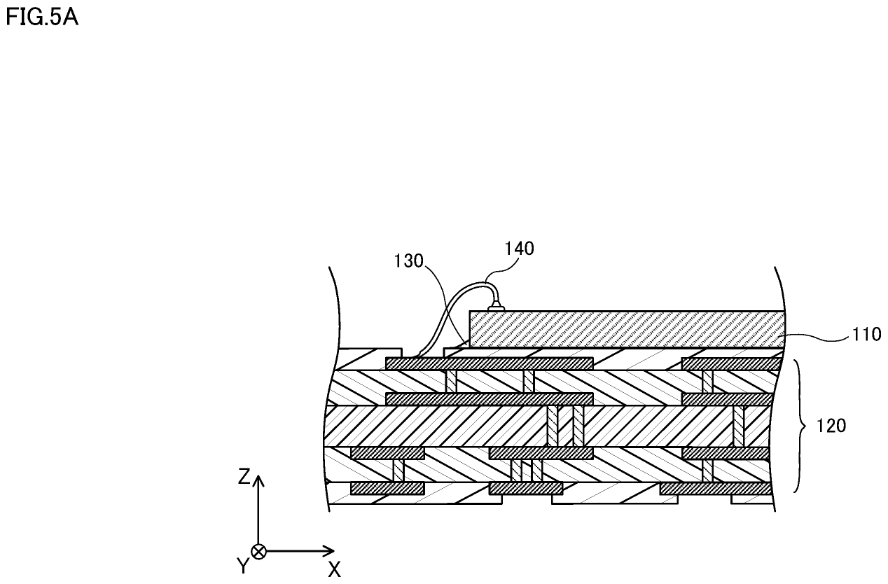

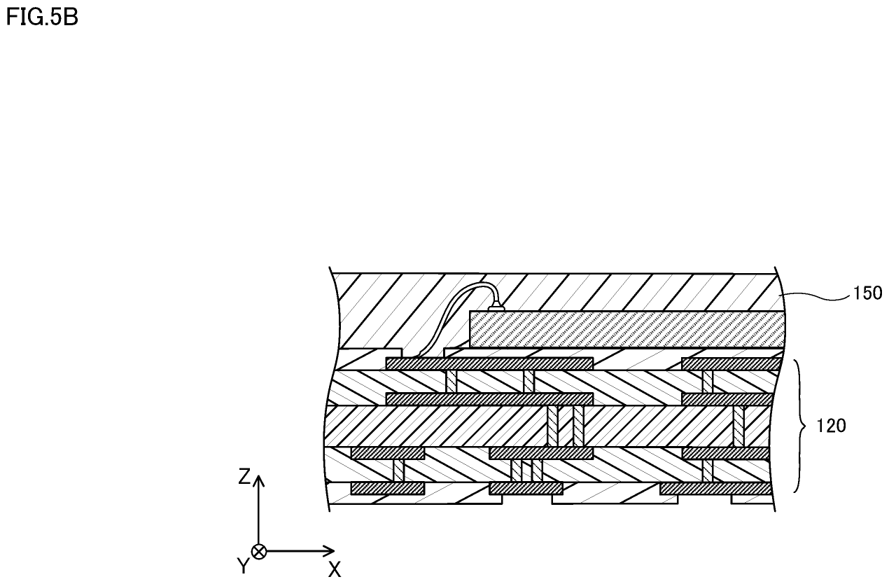

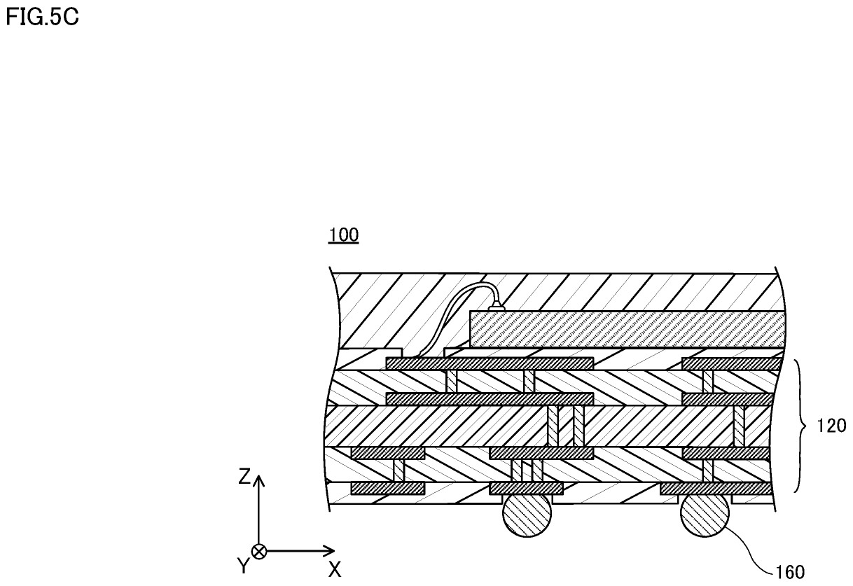

Next, a method of manufacturing the semiconductor device according to the at least one embodiment is described with reference to FIG. 5A to FIG. 5C.

First, as illustrated in FIG. 5A, the conductive adhesive 130 is applied on the front surface of the package substrate 120, and the semiconductor chip 110 is mounted thereon so as to bond the semiconductor chip 110. The electrode pad formed on the front surface of the semiconductor chip 110 and the electrode pad formed on the front surface of the package substrate 120 are electrically connected to each other through the bonding wire 140.

Next, as illustrated in FIG. 5B, the package substrate 120 is held between two molds. The encapsulating resin 150 is poured inside the molds and solidified, to thereby encapsulate the package substrate 120.

Then, as illustrated in FIG. 5C, the conductive bumps 160 are formed on the back surface of the package substrate 120. The resultant is divided into pieces so that the semiconductor device 100 as illustrated in FIG. 5C can be manufactured.

As described above, in the package substrate according to the at least one embodiment of the present invention, the semiconductor chip in which the circuit elements having different operating voltages exist in a mixed manner is mounted on the front surface side thereof, and the electrical paths extending from the front surface side to the back surface side are formed for each of the operating voltages. The package substrate includes: the base material being the flat plate-shaped insulator; the build-up layer which is formed on at least one of the front surface or the back surface of the base material, and in which the wiring layer and the insulating layer are alternately laminated; and the vias which are formed in the base material and the insulating layer, and each electrically connect the wiring layers to each other. The wiring layers having the different operating voltages are arranged so as to be spaced apart by the predetermined distances in accordance with the operating voltages, respectively, and the wiring layers having the same operating voltage are arranged so as to overlap with each other in a plan view at least in the build-up layer.

Thus, the package substrate can increase the potential difference between the wirings without increasing the size thereof in the multilayer substrate, thereby being capable of increasing the reliability.

In the at least one embodiment, the two operating voltages are set to 100 V and 3.3 V. However, the operating voltages are not limited thereto, and can be suitably selected depending on the purpose.

What is claimed is:

1. A package substrate on which a semiconductor chip in which circuit elements having different operating voltages exist in a mixed manner is mounted on a front surface side thereof, and in which electrical paths extending from the front surface side to a back surface side are formed for each of the different operating voltages, the package substrate comprising:
a base material being a flat plate-shaped insulator;
a build-up layer which is formed on at least one of a front surface or a back surface of the base material, and in which a wiring layer and an insulating layer covering the wiring layer are alternately laminated; and
vias which are formed in the base material and the insulating layer, and are each configured to electrically connect the wiring layers to each other,
wherein the wiring layers having the different operating voltages are arranged so as to be spaced apart by predetermined distances in accordance with the different operating voltages, respectively, and
wherein the wiring layers having the same operating voltage are arranged so as to overlap with each other in a plan view at least in the build-up layer.

2. The package substrate according to claim 1, wherein two or more of the vias are formed between the wiring layers having a higher one of the different operating voltages.

3. The package substrate according to claim 2,
wherein the build-up layer is formed on both of the front surface and the back surface of the base material, and
wherein the number of the wiring layers and the number of the insulating layers on the front surface of the base material are the same as the number of the wiring layers and the number of the insulating layers on the back surface of the base material, respectively.

4. The package substrate according to claim 3, wherein, in a region of the build-up layer in which the wiring layers having the same operating voltage are arranged so as to overlap with each other, a wiring width of an outer layer is smaller than a wiring width of an inner layer.

5. A semiconductor device, comprising:
the package substrate of claim 1;
a semiconductor chip mounted on a front surface side of the package substrate; and
an encapsulating resin for encapsulating the semiconductor chip.
